(19) United States
(12) Patent Application Publication
(10) Pub. No.: US 2026/0301848 A1
(43) Pub. Date: Oct. 1, 2026

(54) Data Output Path for a Memory with Double Redundancy

(71) Applicant: QUALCOMM Incorporated, San Diego, CA (US)

(72) Inventors: Debarghya DUTTA, KOLKATA (IN); Kiran DHAMANE, Sangli (IN); Rahul SAHU, Bangalore (IN); Naresh GANDHAM, Bangalore (IN); Akshdeepika LNU, Jalandhar (IN)

(21) Appl. No.: 19/091,612

(22) Filed: Mar. 26, 2025

(51) Int. Cl. G11C 29/00

(52) U.S. Cl. CPC G11C 29/72

(57) ABSTRACT

A memory with double redundancy includes a plurality of global input/output columns each including a data output latch preceding a switch matrix. Each switch matrix is controlled by a corresponding decoder in an address decoding path including a master-slave latch controlled by a memory clock signal and another latch controlled by a sense amplifier enable signal.

### TECHNICAL FIELD

This application relates to memories, and more particularly to a data output path for a memory bank that may replace a pair of defective columns with two redundant columns.

### BACKGROUND

A static random-access memory (SRAM) includes an array of bitcells arranged into rows and columns. To enhance performance such as by lowering the bit line capacitance, the array of bitcells is typically subdivided into banks. Without redundancy, a single error to a bank may render the entire bank inoperative. It is thus conventional for each bank to have a redundant column so that the bank may replace a defective column with the redundant column.

There are two main ways to implement column redundancy: Input/Output (I/O) shifting and sense amplifier shifting. I/O shifting is simpler to implement but requires more semiconductor die space as compared to sense amplifier shifting. In both types of column redundancy, each bank may replace a defective column through the use of a redundant column. A bank may thus replace a single defective column using the redundant column. But defects to two columns in a single bank may render the bank inoperative. Thus, memories with double redundancy have been developed that may correct for two defective columns in a single bank.

### SUMMARY

In accordance with an aspect of the disclosure, a memory is provided that includes: a first global input/output column including a first data output latch having a first output terminal; a second global input/output column including a second data output latch having a second output terminal; a third global input/output column including a third data output latch having a third output terminal; a first address latch configured to latch an address signal responsive to a memory clock signal to provide a first latched address signal; a second address latch configured to latch the first latched address signal responsive to a sense amplifier enable signal to provide a second latched address signal; a decoder configured to decode the second latched address signal to provide a decoded address signal; and a switch matrix configured to couple a selected one of the first output terminal, the second output terminal, and the third output terminal to a switch matrix output terminal responsive to the decoded address signal.

In accordance with another aspect of the disclosure, a method of column redundancy for a memory is provided that includes: latching a first address signal in a first latch responsive to a memory clock signal to provide a first latched address signal; latching the first latched address signal in a second latch responsive to a sense amplifier enable signal to provide a second latched address signal; decoding the second latched address signal to provide a decoded address signal; and selecting a latched data output signal from one of three consecutive columns responsive to the decoded address signal.

In accordance with yet another aspect of the disclosure, an address decoding path for a memory with double column redundancy is provided that includes: a first latch configured to latch an address signal responsive to a memory clock signal to provide a first latched address signal; a second latch configured to latch the first latched address signal responsive to a sense amplifier enable signal to provide a second latched address signal; and a decoder configured to decode the second latched address signal to provide a decoded address signal for controlling a selection of a latched data output from a selected one of three consecutive columns in the memory.

These and additional advantages may be better appreciated through the following detailed description.

### BRIEF DESCRIPTION OF THE DRAWINGS

FIG. 1 illustrates a memory having a double redundancy shift and an improved data output path in accordance with an aspect of the disclosure.

FIG. 2 illustrates a portion of a memory of with double column redundancy in which the data output latches follow the switch matrices.

FIG. 3 illustrates a data output path for a memory with double column redundancy in which the data output latches precede the switch matrices in accordance with an aspect of the disclosure.

FIG. 4 illustrates the address decoding path in the data output path of FIG. 3 in accordance with an aspect of the disclosure.

FIG. 5 illustrates a data output path for a memory with double column redundancy in accordance with an aspect of the disclosure.

FIG. 6 is a flowchart of a double column redundancy method for a memory bank in accordance with an aspect of the disclosure.

FIG. 7 illustrates some example electronic systems incorporating a double column redundancy shift memory in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

The bitcells in an SRAM are arranged into banks with each bank having its own rows and columns. A corresponding pair of bit lines traverses each column whereas a corresponding word line traverses each row of bitcells. Adjacent ones of the bit lines are separated by a bit line pitch. As the transistor size has decreased, the bit line pitch has decreased accordingly. This reduced bit line pitch typically prevents the memory designer from implementing a sense amplifier within the bit line pitch for a column to sense the bit line pair during a read operation. The columns are thus typically arranged into columns with the columns corresponding to a global input/output (GIO) signal being selected by a column multiplexer during a read or write operation. As used herein, the term “GIO column” is thus understood to refer to the columns that are multiplexed within a single bank for a single GIO. In contrast, the term “column” without any further limitation is defined herein to refer to an individual column within a GIO column.

A GIO signal is typically shared between banks such that a global data input latch may latch a data input signal for a GIO column in a first bank or for a corresponding GIO column in a second bank. It may thus be appreciated why a GIO is designated as “global” in that it may be shared between banks and within a bank it is shared by the columns within a GIO column.

The column multiplexing for a GIO depends upon the implementation. In a “MUX2” implementation, each GIO column includes two columns. Similarly, in a “MUX4” implementation, each GIO column includes four columns. The number of redundant columns for a bank depends upon how many defective columns can be replaced and whether IO shifting or sense amplifier shifting is used. For example, the columns in a MUX2 implementation may be denoted as being either odd or even. Each GIO column thus includes one odd column and one even column. Should sense amplifier shifting be used to implement redundancy, a single redundant column may be used in a replacement of either a defective even column or a defective odd column. In contrast, two redundant columns are used for a replacement of a defective MUX2 GIO column if I/O shifting is implemented. It may thus be appreciated that sense amplifier shifting typically has increased density (requires less semiconductor die space to implement) as compared to I/O shifting column redundancy. But the use of sense amplifier shifting generally comes at the cost of increased complexity and switching delays.

Even if I/O shifting is used, the complexity and switching delays may increase if more than one defective column may be replaced in each bank. One factor in the switching delay is the latching of the data output signal in the data output path of a bank with double column redundancy. An advantageous data output path for a memory with double column redundancy using I/O shifting is disclosed herein that offers reduced complexity and reduced switching delays. However, it will be appreciated that the output data path disclosed herein may be implemented in any suitable memory with double column redundancy regardless of whether I/O shifting or sense amplifier shifting is used. Before this advantageous memory is discussed in more detail, some terminology and memory concepts will first be reviewed. In an SRAM bank, each bitcell stores a bit signal and a complement of the bit signal. To access these complementary signals, a bitcell couples to a pair of bit lines. An SRAM bank includes a plurality of such bit line pairs, each bit line pair coupling to a single column of bitcells arranged in rows in the single column according to corresponding word lines. During a write operation, an input latch in a global input/output circuit (which is also denoted as a GIO circuit herein) couples to a selected bitcell through the corresponding bit line pair. Similarly, during a read operation, an output latch in the GIO circuit couples to a selected bitcell through the corresponding bit line pair.

This coupling between a bit line pair (and the corresponding bitcell) and an input/output circuit may be multiplexed as discussed earlier. For example, in a “MUX2” implementation, the bit line pairs may be organized into odd and even pairs within a GIO column. Depending upon the multiplexing, a GIO circuit may couple to a selected bit line pair from a corresponding odd and even pair of bit lines. In a write operation, the GIO circuit may then couple through a write driver and a write column multiplexer to the selected bit line pair. Similarly, during a read operation, the GIO circuit may couple through a read column multiplexer and a sense amplifier to the selected bit line pair. Other types of multiplexing of bit line pairs may be used such as in a “MUX4” implementation in which each input/output circuit may couple to one of four multiplexed columns.

With regard to the column multiplexing, a combination of a write driver, a write column multiplexer, a read column multiplexer, and a sense amplifier may be denoted herein as a “local data path.” The bit lines and bitcells within a GIO column are also denoted herein as a “core.” The following discussion will be directed to implementations in which each I/O circuit is a global I/O circuit, but it will be appreciated that the I/O shifting disclosed herein is applicable to implementations in which the I/O circuits are local I/O circuits. The term “global” I/O circuit is used in that a global I/O circuit may be shared between two banks whereas a local I/O circuit pertains to only one bank. In the following discussion, each global I/O circuit will also be referred to as simply an “I/O circuit” for brevity.

To address the possibility of two defective GIO columns in a single bank, a memory is disclosed herein with double column redundancy. If there are no defective GIO columns in the memory bank, a switch matrix in each GIO circuit is configured to couple to a data output latch in a corresponding default GIO column during a read operation. With regard to what is meant by a “default” GIO column, the GIO columns may be deemed to be indexed such that consecutive GIO columns differ by one with respect to their indices. The GIO circuits have the same indexing. For example, the GIO columns may be deemed to be indexed from one to N, where N is a plural positive integer. The GIO circuits may then have the same indexing. The default GIO column for a given GIO circuit is thus the GIO column having the same index.

Without any errors, each GIO circuit couples through its switch matrix to the corresponding GIO column. But suppose that an ith GIO column is a first defective GIO column in the bank, where i is an integer that is less than N and N is the integer number of GIO columns. From the Nth GIO column to the (i+1)th GIO column, each GIO circuit continues to couple to its default GIO column as discussed previously. From the ith GIO column to the zeroth GIO column, each GIO circuit instead couples to a neighboring or adjacent GIO column to the default GIO column. For example, the ith GIO circuit couples to the (i−1)th GIO column, the (i−1)th GIO circuit couples to the (i−2)th GIO column, and so on such that the zeroth GIO circuit couples to a first redundant GIO column. In the case of such a single defective GIO column, the array of GIO columns may thus be divided into a no-shift region in which each GIO circuit couples to the default GIO column and into a one-shift region in which each GIO circuit couples to a consecutive or neighboring GIO column to the default GIO column.

Should instead there be two defective GIO columns in a single bank, the plurality of GIO columns may instead be divided into a no-shift region, a one-shift region, and a two-shift region. The no-shift region and the one-shift region are as discussed earlier and are demarcated by an initial defective GIO column. A preceding (j−1)th GIO column to a second defective (jth) GIO column is an initial GIO column in the two-shift region, where j is an integer less than I and greater than or equal to zero. Each GIO circuit in the two-shift region couples to a next-to-neighboring GIO column to the GIO circuit's default GIO column. For example, suppose that the initial defective GIO column is the ith GIO column as discussed previously. The second defective GIO column may then be designated as a jth GIO column, where j is an integer that less than i and greater than or equal to zero. A (j+1)th GIO column would then separate the one-shift region from the two-shift region. In such a case, the (j+1)th GIO circuit would couple to the (j−1)th GIO column, the jth GIO circuit would couple to the (j−2)th GIO column, and so on such that a first GIO circuit would couple to the first redundant GIO column and a zeroth GIO circuit would couple to the second redundant GIO column.

In a given bank, the entire plurality of GIO columns forms a no-shift region if there are no defective GIO columns. In such a case, there is no one-shift region nor is there a two-shift region. If there is only one defective GIO column, the plurality of GIO columns is divided into a no-shift region and a one-shift region, there being no two-shift region. If there are two (non-consecutive) defective GIO columns, the plurality of GIO columns is divided into a no-shift region, a one-shift region, and a two-shift region. A memory with two consecutive defective GIO columns may be divided into a no-shift region and a two-shift region (there being no one-shift region).

To identify the defective GIO column(s), the memory may be tested such as at manufacture. The memory may be an embedded memory in a system such as a system on a chip (SoC). The address of the defective GIO columns may then be stored in a read-only memory in the SoC such as an array of fuses. During normal operation of the SoC, a GIO column in the plurality of GIO columns in the memory is addressed for a read or write operation. There are then three possibilities: 1) the addressed GIO column is in a no-shift region, 2) the addressed GIO column is in a one-shift region, and 3) the addressed GIO column is in a two-shift region. To determine which of these three possibilities exists for the addressed GIO column, each I/O circuit includes a redundancy decoder. For brevity, each redundancy decoder will simply be denoted as a decoder in the following discussion.

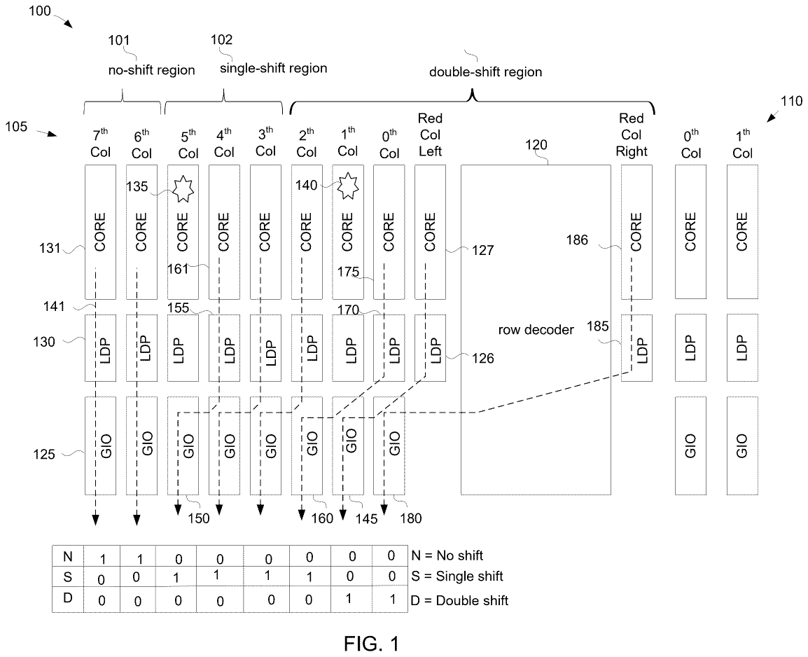

This double-column-redundancy IO shifting may be better appreciated through a consideration of an example memory 100 shown in FIG. 1 that includes a first bank 105 and a second bank 110 separated by a row decoder 120. Each bank includes a plurality of eight GIO columns that each includes a bitcell core and a local data path. The GIO columns are arranged from a zeroth column to a seventh column (for illustration clarity, bank 110 is shown just with two GIO columns). Since there are eight GIO columns in bank 105, there are eight corresponding GIO circuits arranged from a seventh GIO circuit 125 to a zeroth GIO circuit 180. Each GIO circuit includes a data output latch (not illustrated) for the latching of a data output signal during a read operation. In a no-shift state, these GIO circuits couple on a one-to-one basis with a default one of the eight GIO columns in the bank 105. For example, the seventh GIO circuit 125 couples to the seventh GIO column whereas the zeroth GIO circuit 180 would couple to the zeroth GIO column. Each GIO circuit couples to a GIO column through the GIO column's local data path (LDP). For example, the seventh GIO circuit 125 may couple through a LDP 130 to a core 131 for the seventh GIO column. Each GIO column's local data path may include write multiplexers and read multiplexers (not illustrated) as will be explained further herein.

In bank 105, the 5^{th} GIO column has a first defect 135. The 5^{th} GIO column is thus the first defective GIO column in bank 105. The seventh and sixth GIO columns are therefore in a no-shift region 101. As will be explained further herein, each GIO circuit from a 5^{th} GIO circuit 150 through the zeroth GIO circuit 180 will thus be in either a one-shift region 102 or a two-shift region 103. Should the 5th GIO column be the only defective GIO column in bank 105, the one-shift region 102 would extend from the 5^{th} GIO column to the zeroth GIO column. But bank 105 has a second defect 140 in the first GIO column. The first GIO column is thus a second defective GIO column in bank 105. One-shift region 102 thus ends at the third GIO column. Two-shift region 103 extends from the second GIO column to the zeroth GIO column.

In no-shift region 101, each GIO circuit couples to the local data path and core for the GIO circuit's default GIO column. For example, the seventh GIO circuit 125 thus couples through local data path 130 to a core 131 for the 7^{th} GIO column. The coupling for each GIO circuit is represented by an arrow 141. As implied by the designation of “one-shift,” each GIO circuit in one-shift region 102 does not couple to its default GIO column but instead couples through the local data path for the subsequent GIO column to its default GIO column's core. For example, the 5^{th} GIO circuit 150 couples through a local data path 155 to a core 161 for the 4^{th} GIO column. Similarly, each GIO circuit in two-shift region 103 couples through the local data path for the next-to-neighboring GIO column to the GIO circuit's default GIO column. For example, a second GIO circuit 160 in two-shift region 103 couples through a local data path 170 to a core 175 for the 0^{th} GIO column.

A first redundant GIO column (Red Col Left) is located to the left of the row decoder 120 whereas a second redundant GIO column is located to the right of the row decoder 120. The double column redundancy disclosed herein may thus also be designated as a left-right (LR) column redundancy in that it may use the left and right redundant GIO columns. Since bank 105 has two errors, both the right and the left redundant GIO columns are used for its I/O shifting. In the two-shift region 103, a first GIO circuit 145 couples through a first redundant local data path 126 to a core 127 for the left redundant GIO column. Similarly, the zeroth GIO circuit 180 couples through a second redundant local data path 185 to a core 186 for the right redundant GIO column.

To enable the no-shift, single-shift, and double shift behavior, each GIO circuit includes a switch matrix (not illustrated in FIG. 1) that is controlled by a plurality of decoded redundancy address signals. The following discussion of the data output path will be directed to memories in which each shift matrix includes a single level of switches, but it will be appreciated that two levels of switches may be used in alternative implementations. Given this single level, a data output signal to a GIO circuit connects through just one switch in the GIO circuit's switch matrix during a read operation. Similarly, a data input signals from a GIO circuit passes through just one switch in the GIO circuit's switch matrix during a write operation.

As part of this advantageous single-level switch matrix operation, each GIO circuit's redundancy decoder may generate a no-shift (N) address signal, a single-shift(S) address signal, and a double-shift (D) address signal. These decoded redundancy address signals are mutually exclusive such that only one of them may be asserted during a read or write operation. As used herein, a binary signal is deemed to be “asserted” when the binary signal is logically true, regardless of whether the true state is represented using an active-high or active-low convention. The N, S, and D signals are also shown in FIG. 1 for the bank 105. In the no-shift region 101, only the corresponding N signal is asserted for each GIO circuit whereas the S and D signals are both de-asserted. Similarly, only the corresponding S signal is asserted for each GIO circuit in the single-shift region 102. Finally, only the corresponding D signal is asserted for each GIO circuit in the double-shift region.

The arrangement of the GIO circuits from the 7^{th} I/O circuit 125 to the zeroth I/O circuit 180 provides a basis for what is denoted herein as a “preceding” GIO circuit and as a “subsequent” GIO circuit. Excluding the 7th GIO circuit 125, each GIO circuit has a preceding GIO circuit in the GIO circuit arrangement. For example, the second GIO circuit 160 is the preceding GIO circuit to the first GIO circuit 145. More generally, an ith GIO circuit is the preceding GIO circuit to an (i−1)th GIO circuit, where i is a positive integer. Excluding the zeroth GIO circuit 180, each GIO circuit has a subsequent GIO circuit in the GIO circuit arrangement. For example, the first GIO circuit 145 is the subsequent GIO circuit to the second GIO circuit 160. More generally, an (i−1)th GIO circuit is the subsequent GIO circuit to an ith GIO circuit, where i is again a positive integer. Note that this arrangement is arbitrary and may be reversed in alternative implementations in which the two redundant GIO columns would be adjacent the last GIO column as opposed to being adjacent to the zeroth GIO column.

Each of the GIO columns except the right redundant GIO column may be deemed to have a subsequent GIO column. For example, the subsequent GIO column to the left redundant GIO column is the right redundant GIO column. Similarly, each GIO column except the redundant GIO columns may be deemed to have a next-to-subsequent GIO column. For example, the next-to-subsequent GIO column for the zeroth GIO column is the right redundant GIO column. In the same fashion, the next-to-subsequent GIO column for the first GIO column is the left redundant column, the next-to-subsequent GIO column for the second GIO column is the zeroth GIO column, and so on.

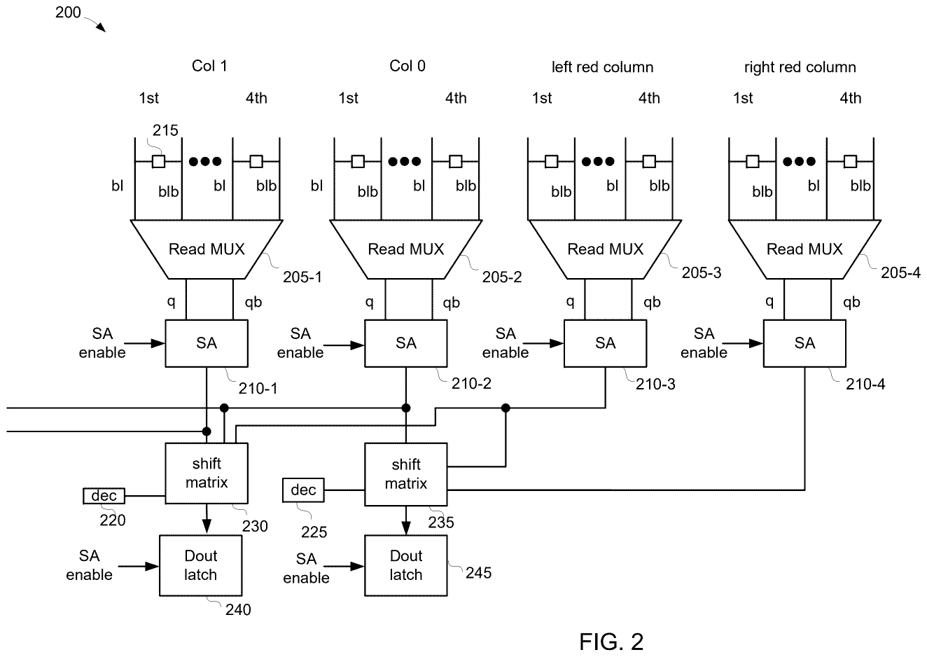

As noted earlier, the term “GIO column” encompasses the local data path and the associated core of multiplexed bit line pair(s) and bitcells. For example, in a “MUX 2” implementation of memory array 100, each of the GIO columns includes both an even bit line pair and an odd bit line pair. Depending upon the column addressing, each GIO circuit then couples to either an even bit line pair or an odd bit line pair in such an implementation. More generally, each GIO column may include a plurality of multiplexed bit line pairs that depends upon the dimension or magnitude of the column multiplexing. A bank 200 is shown in FIG. 2. For illustration clarity, bank 200 only includes the 1^{st} GIO column (Col 1), the zeroth GIO column (Col 0), the left redundant GIO column (left red column) and the right redundant GIO column (right red column). A default GIO circuit for first GIO column is represented by a data output latch 240. Similarly, a default GIO circuit for the zeroth GIO column is represented by a data output latch 245. Each GIO circuit may also include a data input latch but since FIG. 2 is directed to the data output paths, the data input latches are not shown. Each of the first GIO column, the zeroth GIO column, the left redundant GIO column, and the right redundant GIO column includes four bit line pairs ranging from a 1^{st} pair to a 4^{th} pair. Bank 100 is thus a MUX4 (multiplexer 4) bank in that each GIO column includes four columns. Each bit pair is formed by a bit line bl and a complement bit line blb. Each bit line pair couples to a plurality of bitcells arranged into rows. For illustration clarity, only one bitcell is shown for each bit line pair. For example, the first bit line pair in the first GIO column couples to a bitcell 215. The bit line pairs and bitcells for each GIO column forms the GIO column's core. The local data output path in each GIO column includes a read column multiplexer and a sense amplifier (SA). The first GIO column thus includes a sense amplifier 210-1 and a read column multiplexer 205-1, the zeroth GIO column includes a sense amplifier 210-2 and a read column multiplexer 205-2, the left redundant GIO column includes a sense amplifier 210-3 and a read column multiplexer 205-3, and the second redundant GIO column includes a sense amplifier 210-4 and a read column multiplexer 205-4. Depending upon a stored binary value q and its complement qb, each sense amplifier produces a data output signal from the corresponding sensed column.

Each GIO column has its own shift matrix. The first GIO column thus includes a shift matrix 230 that may select the data output signal from the sense amplifiers 210-1, 210-2, and 210-3. Similarly, the zeroth GIO column includes a shift matrix 235 that may select from the data output signal from the sense amplifiers 210-2, 210-3, and 210-4. If there are no errors in the first GIO column and the second GIO column then the shift matrices 230 and 235 would be a no-shift region. In that case, each data output latch latches the data output signal from the default GIO column. For example, the data output signal from the sense amplifier 210-1 would route through the shift matrix 230 to be latched in the data output latch 240. Similarly, the data output signal from the sense amplifier 210-2 would route through the shift matrix 235 to be latched in the data output latch 245. Neither the first redundant GIO column nor the second redundant GIO column is used in that case.

Should the first and zeroth GIO columns be included in a one-shift region, the shift matrix 230 routes the data output signal from the sense amplifier 210-2 to be latched into the data output latch 240. Similarly, the shift matrix 235 routes the data output signal from the sense amplifier 210-3 to be latched into the data output latch 245. Each GIO column includes a decoder that controls whether the GIO column's shift matrix (which may also be denoted as shifting logic) shifts or not. Each decoder is shown separately in FIG. 2 from its GIO column for illustration purposes. For example, a decoder 220 controls the shifting of the shift matrix 230. Similarly, a decoder 225 controls the shifting of the shift matrix 235.

Should the first and the zeroth GIO columns be included in a two-shift region, the data output signal from the sense amplifier 210-4 routes through the shift matrix 235 for the zeroth GIO column to be latched in the data output latch 245. Similarly, the data output signal from the sense amplifier 210-3 for the first redundant GIO column routes through the shift matrix 230 for the first GIO column to be latched in the data output latch 240. Each sense amplifier 210-1 through 210-4 is enabled to sense the corresponding data output signal by an assertion of a sense amplifier enable (SA enable) signal. It is convenient for the sense amplifier enable signal to also control whether the data output latches such as the data output latches 240 and 245 to be transparent or closed. As defined herein, a latch is deemed to be transparent when it responds to an input data signal by latching the input data signal. Conversely, a latch is deemed herein to be closed when it does not respond to the input data signal. While the sense amplifier enable signal for a GIO column is not asserted, the corresponding data output latch is closed and thus will not change its stored content regardless of whether a data output signal changes its binary value. But when the sense amplifier signal is asserted, the data output latch is transparent and will thus respond to and latch whatever is the binary value of the data output signal from the corresponding shift matrix.

The control of the data output latches by the sense amplifier enable signal raises an issue that may be better appreciated with reference to FIG. 1 in conjunction with FIG. 2. One issue is that in a double-shift configuration, the data output signal from the sense amplifier 210-4 propagates across the row decoder 120 and the first redundant GIO column before it routes through the shift matrix 235 to be latched in the data output latch 245. There is thus an appreciable resistance-capacitance (RC) propagation delay for such a relatively-extended signal routing. As a result, the pulse width for the sense enable signal assertion or pulsing should be sufficiently long such that the data output latch 245 is still transparent when it finally receives the data output signal from the second redundant GIO column. But maintaining the sense amplifier enable assertion over a longer duration results in a slower read operation, which in turn undesirably slows the memory operation speed.

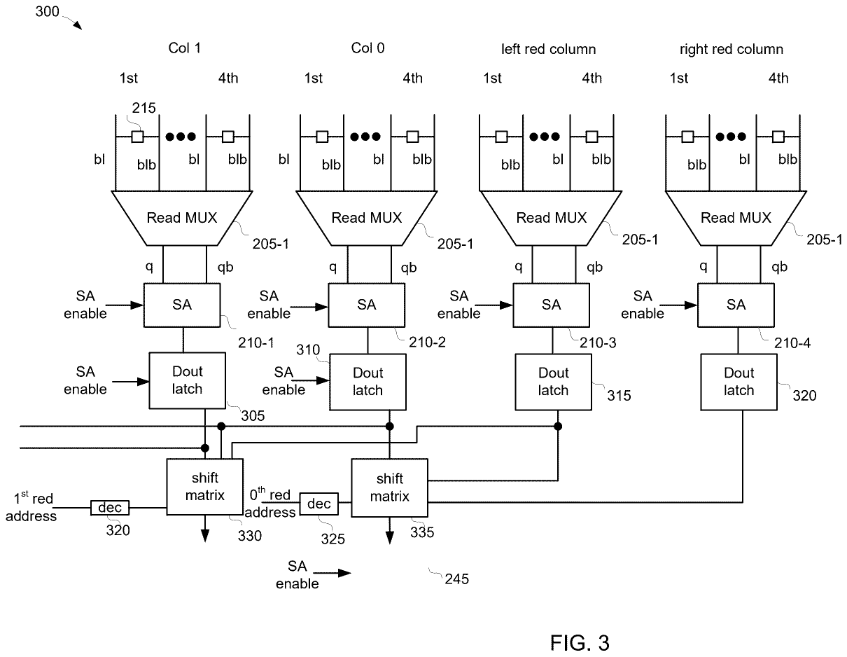

A bank 300 with an improved data output path is shown in FIG. 3 in which the memory speed is advantageously increased despite the possibility of a double redundancy shifting. For illustration clarity, FIG. 3 shows only the 1^{st} GIO column (Col 1), the zeroth GIO column (Col 0), the left redundant GIO column (left red column) and the right redundant GIO column (right red column) of bank 300 but it will be appreciated that bank 300 may include additional GIO columns. The read column multiplexers 205-1 through 205-4, the sense amplifiers 210-1 through 210-4, and the corresponding bit lines and bitcells are arranged as discussed for bank 200. In contrast to bank 200, each GIO column in bank 300 includes a data output latch that latches a data output signal before the data output signal is routed through a shift matrix/shifting logic. For example, the first GIO column includes a data output latch 305 that latches the data output signal from the sense amplifier 210-1 in response to the assertion of the sense enable signal. Similarly, the zeroth GIO column includes a data output latch 310 that latches the data output signal from the sense amplifier 210-2, the first redundant GIO column includes a data output latch 315 that latches the data output signal from the sense amplifier 210-3, and the second redundant GIO column includes a data output latch 320 that latches the data output signal from the sense amplifier 210-4.

A shift matrix 330 for the first GIO column is analogous to the shift matrix 230 except that the shift matrix 330 selects from the latched data output signals from the data output latches 305, 310, and 315 as opposed to selecting from the data output signals from the sense amplifiers 210-1, 210-2, and 210-3. A decoder 320 decodes a redundancy address (1^{st} red address) for the first GIO to produce the decoded address signal such as the N, S, and D signals discussed with regard to FIG. 1 to control the shifting by the shift matrix 330. Similarly, a shift matrix 335 for the zeroth GIO column is analogous to the shift matrix 235 except that the shift matrix 335 selects from the latched data output signals from the data output latches 310, 315, and 320 as opposed to selecting from the data output signals from the sense amplifiers 210-2, 210-3, and 210-4. A decoder 325 produces the decoded address signal such as the N, S, and D signals discussed with regard to FIG. 1 to control the shifting by the shift matrix 335.

The production of the redundancy address signals that are decoded by the decoders such as the decoders 320 and 325 is not synchronous with the reading of the data output signals in that the address signals for a subsequent read cycle may be produced while a current read cycle is still being processed. The address signals for a given memory cycle are thus only valid to the corresponding decoder for a sufficient hold time and may then change. Each read cycle is synchronous with and timed by a memory clock cycle. Since the shift matrices follow the data output latches, the address signals for a given read operation should stay active even after a read operation has ended. But since the address signals may change during the later portion of a read cycle, a corresponding address latch (not illustrated) latches the address signals for each decoder so that the decoded redundancy address signals for a given shift matrix are static throughout a read operation clock cycle. A single address latch that is gated by the memory clock signal to latch a redundancy address signal may be unsuitable since such a latch would allow the address signals to change during a read operation. As will be discussed further herein, each address latch may thus be a master/slave latch combination that is clocked by the memory clock signal such that the master latch is transparent with respect to one binary state of the memory clock signal and closed during a second binary state of the memory clock signal whereas the slave latch is transparent during the second binary state of the memory clock signal and closed during the first binary state.

A latched address signal from the master latch may be unsuitable for being decoded by the corresponding decoder since such a latched address signal may change during a read operation cycle. In contrast, a latched address signal from the slave latch will stay constant during a given read operation. But a write operation may follow a read operation. The redundancy address signal may then change, which causes the decoded redundancy address signals to change and thus cause the shifting through the corresponding shift matrix to change during the write operation. The data output signal could then change unexpectedly during the write operation, which may cause an error condition.

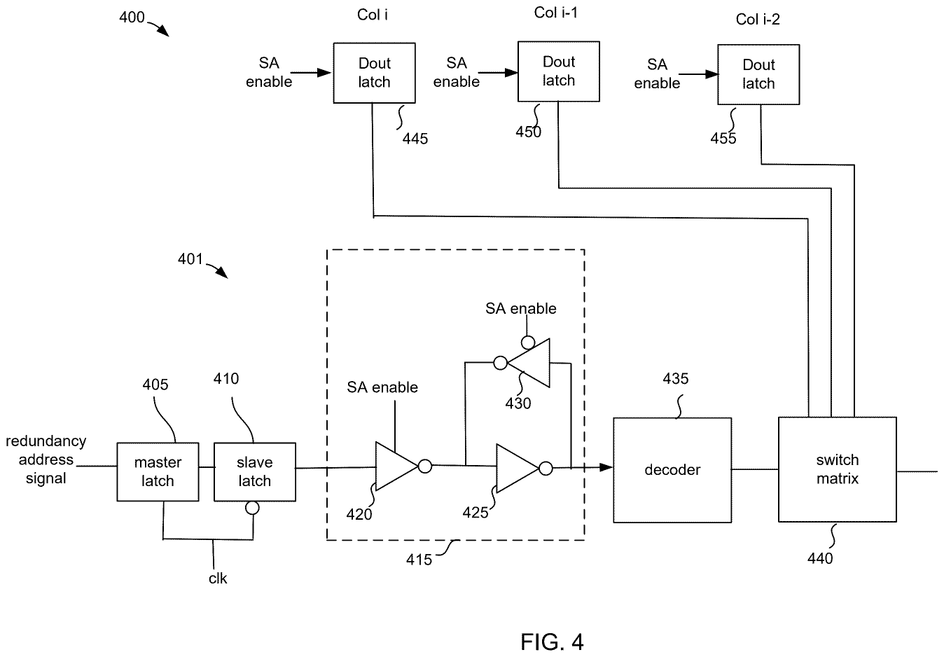

To eliminate these issues, a memory data output path 400 is provided with an address decoding path 401 as shown in FIG. 4. The data output path 400 is the data output path for an ith column (Col i), where i is the integer index for the ith column. A switch matrix 440 (which may also be denoted as a shifting logic circuit) selects a data output signal from a data output latch 445 for the ith column should the ith column be in a no-shift region during a read operation. If the ith column is in a one-shift region during a read operation, the switch matrix 440 selects for a data output signal from a data output latch 450 for an (i−1)th column (Col i−1), which is the subsequent column to the ith column. Similarly, if the ith column is in a two-shift region during a read operation, the switch matrix 440 selects for a data output signal from a data output latch 455 for an (i−2)th column (Col i−1), which is the next-to-subsequent column to the ith column.

The read operation is triggered by a memory clock signal (clk). The memory clock signal has a rising edge (transitions from ground to the memory power supply voltage in a beginning portion of the read operation and has a falling edge (transitions from the memory power supply voltage to ground) while a sense amplifier enable signal (SA enable) is asserted for the read operation. The pulsing of the sense amplifier enable signal causes the data output latches 445, 450, and 455 to be transparent so as to latch their respective data output signals. The pulsing of the memory clock signal also causes a master latch 405 in the address decoding path 401 to be transparent to latch a redundancy address signal for the read operation. A slave latch 410 is transparent when the memory clock signal is discharged to latch a latched redundancy address output signal from the master latch 410. A latched address signal from the slave latch 410 could be decoded by a decoder 435 to provide a decoded redundancy address signal to control the shifting by the switch matrix 440. But as noted earlier, suppose a write operation follows the read operation. A new address signal may then be latched through the master latch 405 and slave latch 410 such that the switch matrix 440 switches its data output latch selection during the write operation, which may cause the data output signal from the shifting logic 440 to change undesirably during the write operation. To prevent this change, the latched redundancy address signal from the slave latch 410 is latched by a latch 415 that is transparent while the sense amplifier enable signal is pulsed and is closed otherwise. The sense amplifier enable signal is only pulsed during a read operation and will thus remain discharged during a write operation. The selection by switch matrix 440 will thus be static during a write operation, which is quite advantageous in that the location of the data output latches 445, 450, 455 enables a shorter sense amplifier enable pulse (and thus a faster memory speed) yet the undesirable change in the data output signal during a write operation is eliminated. A memory with double redundancy shifting may thus be provided that has an advantageously fast operating speed. The combination of the master and slave latches 405 and 410 is also denoted herein as a first address latch or as a first latch. The slave latch 410 is also denoted herein as a first latch. Similarly, the latch 415 is also denoted herein as a second address latch or as a second latch.

As noted earlier, a data output path such as the data output path 400 in which the switch matrices follow the data output latches for the columns may be implemented in any suitable memory with double column redundancy shifting regardless of the switch matrix implementation. A particularly advantageous implementation of the data output path, however, may be realized in a double-column-redundancy memory with one-level switch matrices. A switch matrix is deemed to be one-level herein because the routing of any latched data output signal through the switch matrix involves the propagation of the latched data output signal through only a single switch. In contrast, the routing of a latched data output signal through a switch matrix with two-level switching would pass the latched data output signal through at least two switches. A double-redundancy-shifting memory with an advantageous data output path and single-level switching will now be discussed in more detail. As used herein, a “switch matrix” is deemed to include a plurality of switches.

### Example Switch Matrices

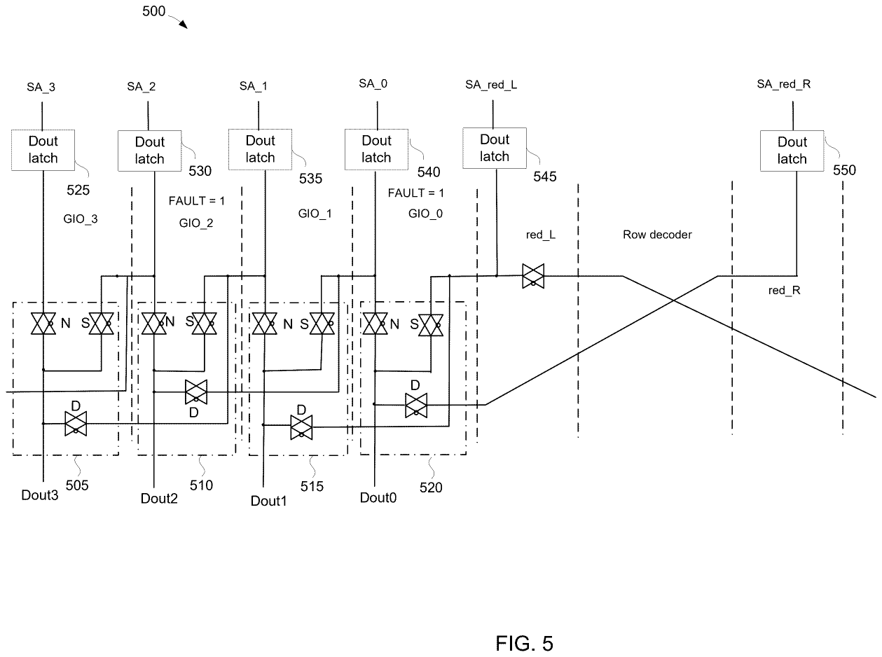

Performing the selection between a no-shift, a single-shift, and a double-shift within a single-level switch matrix uses only three switches. An example data output path 500 for a bank is shown in FIG. 5. For illustration brevity, the bank includes only a third column (GIO_3), a second GIO column (GIO_2), a first GIO column (GIO_1), and a zeroth GIO column (GIO_0). There is also a left redundant GIO column (red_L) and a right redundant GIO column (red_R) that are separated by a row decoder for the first bank and for a second bank (not illustrated).

An output terminal of each GIO column's sense amplifier is also shown. For example, the third GIO column includes a sense amplifier output terminal (SA_3) coupled to an input terminal of a data output latch 525. Similarly, the second GIO column includes a sense amplifier output terminal SA_2 coupled to an input terminal of a data output latch 530. In addition, the first GIO column includes a sense amplifier output terminal SA_1 coupled to a data output latch 535. Similarly, the zeroth GIO column includes a sense amplifier output terminal SA_0 coupled to an input terminal of a data output latch 540. Moreover, the left redundant GIO column includes a sense amplifier output terminal SA_red_L coupled to an input terminal of a data output latch 545. Finally, the right redundant GIO column includes a sense amplifier output terminal SA_red_R coupled to an input terminal of a data output latch 550. For illustration clarity, the corresponding sense amplifiers, column multiplexers, and column cores are not shown in FIG. 4.

Each of the non-redundant GIO columns includes a switch matrix. For example, the third GIO column includes a switch matrix 505. Similarly, the second GIO column includes a switch matrix 510. In the same fashion, the first GIO column includes a switch matrix 515. Finally, the zeroth GIO column includes a switch matrix 520. Each switch matrix includes three switches such as formed by three corresponding transmission gates. A first transmission gate for each switch matrix is controlled by the GIO circuit's no-shift signal (N) and is thus also designated as a switch N. Similarly, a second transmission gate for each switch matrix is controlled by the GIO circuit's single-shift signal(S) and is thus also designated as a switch S. Finally, a third transmission gate for each switch matrix is controlled by the GIO circuit's double-shift signal (D) and is thus also designated as a switch D. The switch S couples between an output terminal for the GIO column's default data output latch and an output terminal for the switch matrix. For example, the transmission gate N in the switch matrix 505 for the third GIO circuit couples between an output terminal of the data output latch 525 and an output terminal Dout3 for the switch matrix 505.

Each switch S connects between an output terminal for the subsequent GIO column's data output latch and an output terminal for the switch matrix. For example, the transmission gate S in the switch matrix 510 for the second GIO column connects between an output terminal of the data output latch 535 for the first GIO column and the output terminal Dout2 to the switch matrix 510. As used herein, the term “connects” or “connected” with respect to a switch are defined as a direct electrical connection through the switch and excludes a coupling through additional switches. Each switch D connects between an output terminal for the next-to-subsequent GIO column and an input terminal for the GIO circuit's data output latch. For example, the transmission gate D for the switch matrix 515 of the first GIO column connects between an output terminal of the data output latch 545 for the left redundant GIO column and an output terminal Dout1 for the switch matrix 515. Similarly, the transmission gate D for the switch matrix 520 of the zeroth GIO column connects between an output terminal of the data output latch 550 of the right redundant GIO column and an output terminal Dout0 of the switch matrix 520.

The third GIO column is in a no-shift region such that only the transmission gate N is open (conducting) in the switch matrix 505. The transmission gates S and D in the switch matrix 505 are thus closed (non-conducting). The second GIO column is the initial faulty column in the bank. Thus, the transmission gate S in the switch matrix 510 is open whereas the transmission gates D and N in the switch matrix 310 are closed. The first GIO column is also in a one-shift region for the bank. Thus, the transmission gate S in the switch matrix 515 is open whereas the transmission gates N and D are closed. The zeroth GIO column is a second defective column in the bank and is therefore in a two-shift region. The transmission gate D in the switch matrix 520 is thus open whereas the transmission gates N and S in the switch matrix 520 are closed. The redundancy address latching and decoding for the switch matrices 505, 510, 515, and 520 is not shown in FIG. 5 for illustration clarity but may be performed as discussed for FIG. 4. In addition, the sense amplifier enable signal control of the data output latches 525, 530, 540, 545, and 550 is also not shown in FIG. 5 for illustration clarity. Each decoder (not illustrated) for the switch matrices would be configured to decode the latched redundancy address signals to produce the N, S, and D control signals as the decoded redundancy address signals.

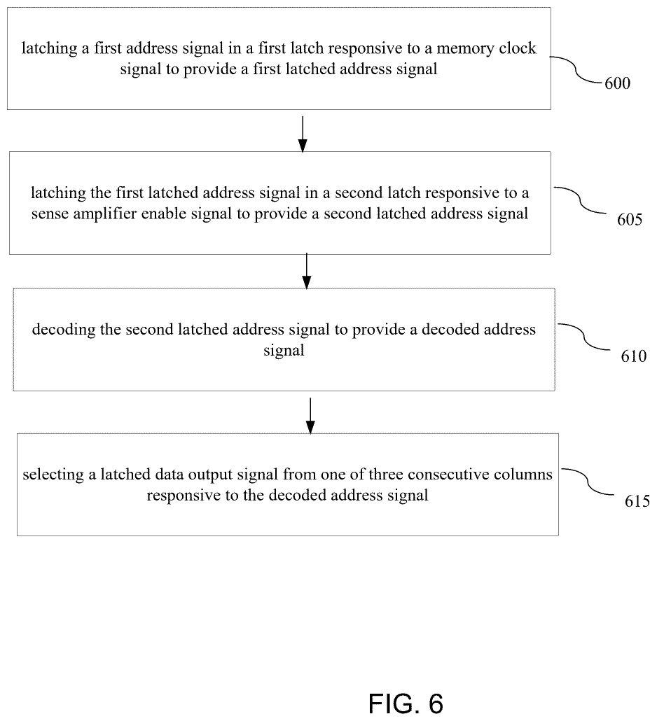

A double redundancy shift method of operation for a memory will now be discussed with regard to the flowchart of FIG. 6. The method includes an act 600 of latching a first address signal in a first latch responsive to a memory clock signal to provide a first latched address signal. The latching in the slave latch 410 is an example of act 600. The method also includes an act 605 of latching the first latched address signal in a second latch responsive to a sense amplifier enable signal to provide a second latched address signal. The latching in the latch 415 is an example of act 605. In addition, the method includes an act 610 of decoding the second latched address signal to provide a decoded address signal. The decoding in any of the decoders 220, 225, and 435 is an example of act 610. Finally, the method includes an act 615 of selecting a latched data output signal from one of three consecutive columns responsive to the decoded address signal. The selection in any of the switch matrices 230, 235, 330, 335, and 440 is an example of act 615.

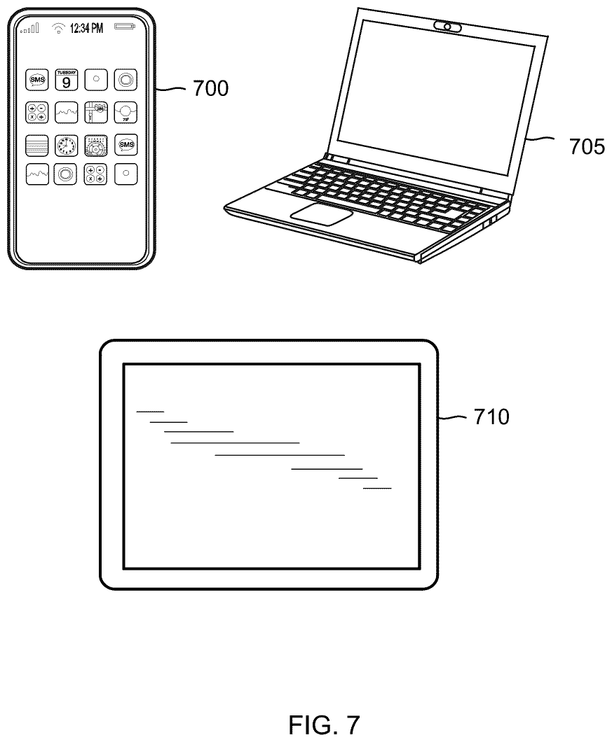

A memory as disclosed herein may be incorporated into a wide variety of electronic systems. For example, as shown in FIG. 7, a cell phone 700, a laptop 705, and a tablet PC 710 may all include a memory having a double redundancy shift data path in accordance with the disclosure. Other exemplary electronic systems such as a music player, a video player, a communication device, and a personal computer may also be configured with memories constructed in accordance with the disclosure.

The disclosure will now be summarized by the following example clauses:

Clause 1. A memory, comprising:
a first global input/output column including a first data output latch having a first output terminal;
a second global input/output column including a second data output latch having a second output terminal;
a third global input/output column including a third data output latch having a third output terminal;
a first address latch configured to latch an address signal responsive to a memory clock signal to provide a first latched address signal;
a second address latch configured to latch the first latched address signal responsive to a sense amplifier enable signal to provide a second latched address signal;
a decoder configured to decode the second latched address signal to provide a decoded address signal; and
a switch matrix configured to couple a selected one of the first output terminal, the second output terminal, and the third output terminal to a switch matrix output terminal responsive to the decoded address signal.

Clause 2. The memory of clause 1, wherein the first data output latch, the second data output latch, and the third data output latch are each configured to latch a corresponding data output signal responsive to the sense amplifier enable signal.

Clause 3. The memory of any of clauses 1-2, wherein the first address latch comprises a master latch in series with a slave latch.

Clause 4. The memory of clause 3, wherein the master latch is configured to be transparent responsive to a first binary value of the memory clock signal and to be closed responsive to a second binary value of the memory clock signal, and wherein the slave latch is configured to be transparent responsive to the second binary value of the memory clock signal and to be closed responsive to the first binary value of the memory clock signal.

Clause 5. The memory of any of clauses 1-4, wherein the second address latch is configured to be transparent responsive to the sense amplifier enable signal being charged to a memory power supply voltage and to be closed responsive to the sense amplifier enable signal being discharged to ground.

Clause 6. The memory of any of clauses 1-5, wherein the first global input/output column further includes:
a first column multiplexer configured to select from a first plurality of columns of bitcells to provide a selected pair of bit lines; and
a first sense amplifier configured to sense a first data output signal from the selected pair of bit lines responsive to an assertion of the sense amplifier enable signal.

Clause 7. The memory of any of clauses 1-6, further comprising:
a row decoder, wherein the second global input/output column comprises a first redundant global input/output column adjacent a first side of the row decoder, and
wherein the third global input/output column comprises a second redundant global input/output column adjacent a second side of the row decoder.

Clause 8. The memory of any of clauses 1-6, wherein the switch matrix comprises:
a first switch connected between the first output terminal and the switch matrix output terminal;
a second switch connected between the second output terminal and the switch matrix output terminal; and
a third switch connected between the third output terminal and the switch matrix output terminal.

Clause 9. The memory of clause 8, wherein the first switch, the second switch, and the third switch each comprises a transmission gate.

Clause 10. The memory of any of clauses 1-9, wherein the switch matrix includes no additional switches.

Clause 11. The memory of any of clauses 1-10, wherein the memory is a static random access memory (SRAM) included within a cellular telephone.

Clause 12. A method of column redundancy for a memory, comprising;
latching a first address signal in a first latch responsive to a memory clock signal to provide a first latched address signal;
latching the first latched address signal in a second latch responsive to a sense amplifier enable signal to provide a second latched address signal;
decoding the second latched address signal to provide a decoded address signal;
selecting a latched data output signal from one of three consecutive columns responsive to the decoded address signal.

Clause 13. The method of clause 12, further comprising:
latching a redundancy address signal in a master latch responsive to the memory clock signal to provide the first address signal, wherein the latching the first address signal in the first latch comprises latching the first address signal in a slave latch.

Clause 14. The method of clause 13, wherein the latching of the redundancy address signal in the master latch is responsive to a first binary state of the memory clock signal, and wherein the latching of the first address signal in the slave latch is responsive to a second binary state of the memory clock signal.

Clause 15. The method of any of clauses 12-14, wherein the latching of the first latched address signal in the second latch is responsive to a charging of the sense amplifier enable signal to a memory power supply voltage.

Clause 16. The method of any of clauses 12-15, wherein the latching of the first address signal in the first latch occurs during a first cycle of the memory clock signal, and wherein the latching of the first latched address signal in the second latch occurs during a second cycle of the memory clock signal that follows the first cycle.

Clause 17. An address decoding path for a memory with double column redundancy, comprising:
a first latch configured to latch an address signal responsive to a memory clock signal to provide a first latched address signal;
a second latch configured to latch the first latched address signal responsive to a sense amplifier enable signal to provide a second latched address signal; and
a decoder configured to decode the second latched address to provide a decoded address signal for controlling a selection of a latched data output from a selected one of three consecutive columns in the memory.

Clause 18. The address decoding path of clause 17, wherein the first latch comprises a master latch in series with a slave latch.

Clause 19. The address decoding path of clause 18, wherein the master latch is configured to be transparent responsive to a first binary value of the memory clock signal and to be closed responsive to a second binary value of the memory clock signal, and wherein the slave latch is configured to be transparent responsive to the second binary value of the memory clock signal and to be closed responsive to the first binary value of the memory clock signal.

Clause 20. The address decoding path of any of clauses 17-19, wherein the second latch is configured to be transparent responsive to the sense amplifier enable signal being charged to a memory power supply voltage and to be closed responsive to the sense amplifier enable signal being discharged to ground.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A memory, comprising:
a first global input/output column including a first data output latch having a first output terminal;
a second global input/output column including a second data output latch having a second output terminal;
a third global input/output column including a third data output latch having a third output terminal;
a first address latch configured to latch an address signal responsive to a memory clock signal to provide a first latched address signal;
a second address latch configured to latch the first latched address signal responsive to a sense amplifier enable signal to provide a second latched address signal;
a decoder configured to decode the second latched address signal to provide a decoded address signal; and
a switch matrix configured to couple a selected one of the first output terminal, the second output terminal, and the third output terminal to a switch matrix output terminal responsive to the decoded address signal.

2. The memory of claim 1, wherein the first data output latch, the second data output latch, and the third data output latch are each configured to latch a corresponding data output signal responsive to the sense amplifier enable signal.

3. The memory of claim 1, wherein the first address latch comprises a master latch in series with a slave latch.

4. The memory of claim 3, wherein the master latch is configured to be transparent responsive to a first binary value of the memory clock signal and to be closed responsive to a second binary value of the memory clock signal, and wherein the slave latch is configured to be transparent responsive to the second binary value of the memory clock signal and to be closed responsive to the first binary value of the memory clock signal.

5. The memory of claim 1, wherein the second address latch is configured to be transparent responsive to the sense amplifier enable signal being charged to a memory power supply voltage and to be closed responsive to the sense amplifier enable signal being discharged to ground.

6. The memory of claim 1, wherein the first global input/output column further includes:
a first column multiplexer configured to select from a first plurality of columns of bitcells to provide a selected pair of bit lines; and
a first sense amplifier configured to sense a first data output signal from the selected pair of bit lines responsive to an assertion of the sense amplifier enable signal.

7. The memory of claim 1, further comprising:
a row decoder, wherein the second global input/output column comprises a first redundant global input/output column adjacent a first side of the row decoder, and wherein the third global input/output column comprises a second redundant global input/output column adjacent a second side of the row decoder.

8. The memory of claim 1, wherein the switch matrix comprises:
a first switch connected between the first output terminal and the switch matrix output terminal;
a second switch connected between the second output terminal and the switch matrix output terminal; and
a third switch connected between the third output terminal and the switch matrix output terminal.

9. The memory of claim 8, wherein the first switch, the second switch, and the third switch each comprises a transmission gate.

10. The memory of claim 1, wherein the switch matrix includes no additional switches.

11. The memory of claim 1, wherein the memory is a static random access memory (SRAM) included within a cellular telephone.

12. A method of column redundancy for a memory, comprising;
latching a first address signal in a first latch responsive to a memory clock signal to provide a first latched address signal;
latching the first latched address signal in a second latch responsive to a sense amplifier enable signal to provide a second latched address signal;
decoding the second latched address signal to provide a decoded address signal; and
selecting a latched data output signal from one of three consecutive columns responsive to the decoded address signal.

13. The method of claim 12, further comprising:
latching a redundancy address signal in a master latch responsive to the memory clock signal to provide the first address signal, wherein the latching the first address signal in the first latch comprises latching the first address signal in a slave latch.

14. The method of claim 13, wherein the latching of the redundancy address signal in the master latch is responsive to a first binary state of the memory clock signal, and wherein the latching of the first address signal in the slave latch is responsive to a second binary state of the memory clock signal.

15. The method of claim 12, wherein the latching of the first latched address signal in the second latch is responsive to a charging of the sense amplifier enable signal to a memory power supply voltage.

16. The method of claim 12, wherein the latching of the first address signal in the first latch occurs during a first cycle of the memory clock signal, and wherein the latching of the first latched address signal in the second latch occurs during a second cycle of the memory clock signal that follows the first cycle.

17. An address decoding path for a memory with double column redundancy, comprising:
a first latch configured to latch an address signal responsive to a memory clock signal to provide a first latched address signal;
a second latch configured to latch the first latched address signal responsive to a sense amplifier enable signal to provide a second latched address signal; and
a decoder configured to decode the second latched address signal to provide a decoded address signal for controlling a selection of a latched data output from a selected one of three consecutive columns in the memory.

18. The address decoding path of claim 17, wherein the first latch comprises a master latch in series with a slave latch.

19. The address decoding path of claim 18, wherein the master latch is configured to be transparent responsive to a first binary value of the memory clock signal and to be closed responsive to a second binary value of the memory clock signal, and wherein the slave latch is configured to be transparent responsive to the second binary value of the memory clock signal and to be closed responsive to the first binary value of the memory clock signal.

20. The address decoding path of claim 18, wherein the second latch is configured to be transparent responsive to the sense amplifier enable signal being charged to a memory power supply voltage and to be closed responsive to the sense amplifier enable signal being discharged to ground.
